(19) United States
(12) Patent Application Publication
(10) Pub. No.: US 2010/0328869 A1
(43) Pub. Date: Dec. 30, 2010

(54) PORTABLE ELECTRONIC DEVICE

(75) Inventors: Adjo Poorter, Heerlen (NL); Jan Mathijs Meijers, Maastricht (NL)

Correspondence Address: LIU & LIU, 444 S. FLOWER STREET, SUITE 1750, LOS ANGELES, CA, 90071, US

(73) Assignee: TPO DISPLAYS CORP., Chu-Nan (TW)

(21) Appl. No.: 12/707,648

(22) Filed: Feb. 17, 2010

Related U.S. Application Data
(60) Provisional application No. 61/220,447, filed on Jun. 25, 2009.

(51) Int. Cl. G06F 1/16; H05K 5/00

(52) U.S. Cl. 361/679.3; 361/679.01

(57) ABSTRACT

A portable electronic device is provided. The portable electronic device includes a frame, a display and at least one spacing element. The display includes a panel, wherein the panel is disposed in the frame. The spacing element is adhered to the frame, and disposed between the frame and the panel.

### CROSS REFERENCE TO RELATED APPLICATIONS

This application claims the benefit of U.S. Provisional Application No. 61/220,447, Jun. 25, 2009.

### BACKGROUND OF THE INVENTION

1. Field of the Invention

The present invention relates to a portable electronic device, and in particular relates to a portable electronic device with a display, such as telecom and automotive application devices.

2. Description of the Related Art

Conventional portable electronic device includes a display, a metal frame and a plastic insert. The display includes a glass panel. The plastic insert can be a separate part assembled to the metal frame. The plastic insert ensures existence of a gap between the glass panel and the metal frame, and prevents the glass panel from contacting the metal frame.

However, with miniaturization of portable electronic devices, the plastic insert is unable to decrease the gap between the glass panel and the metal frame due to dimensional limitations. A process where plastic is insert molded into a frame can be an intermediate solution until also this will reach its dimensional limitations.

### BRIEF SUMMARY OF THE INVENTION

A detailed description is given in the following embodiments with reference to the accompanying drawings.

A portable electronic device is provided. The portable electronic device includes a frame, a display and at least one spacing element. The display includes a panel, wherein the panel is disposed in the frame. The spacing element is adhered to the frame, and disposed between the frame and the panel.

For the portable electronic device of the invention, the gap between the frame and the panel is further reduced (for example, reduced to 0.02 mm to 1 mm). Therefore, further miniaturization of portable electronic devices can be achieved. The portable electronic device can be a mobile phone, Personal Digital Assistant (PDA), or other electronic devices.

### BRIEF DESCRIPTION OF THE DRAWINGS

The present invention can be more fully understood by reading the subsequent detailed description and examples with references made to the accompanying drawings, wherein:

FIG. 1 shows a display module of a portable electronic device of an embodiment of the invention;

FIG. 2 is an assembly view of the display module of FIG. 1;

FIG. 3 is an enlarged view of portion A of FIG. 1;

FIG. 4 is an enlarged view of portion B of FIG. 2; and

FIG. 5 shows an assembling method of an embodiment of the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

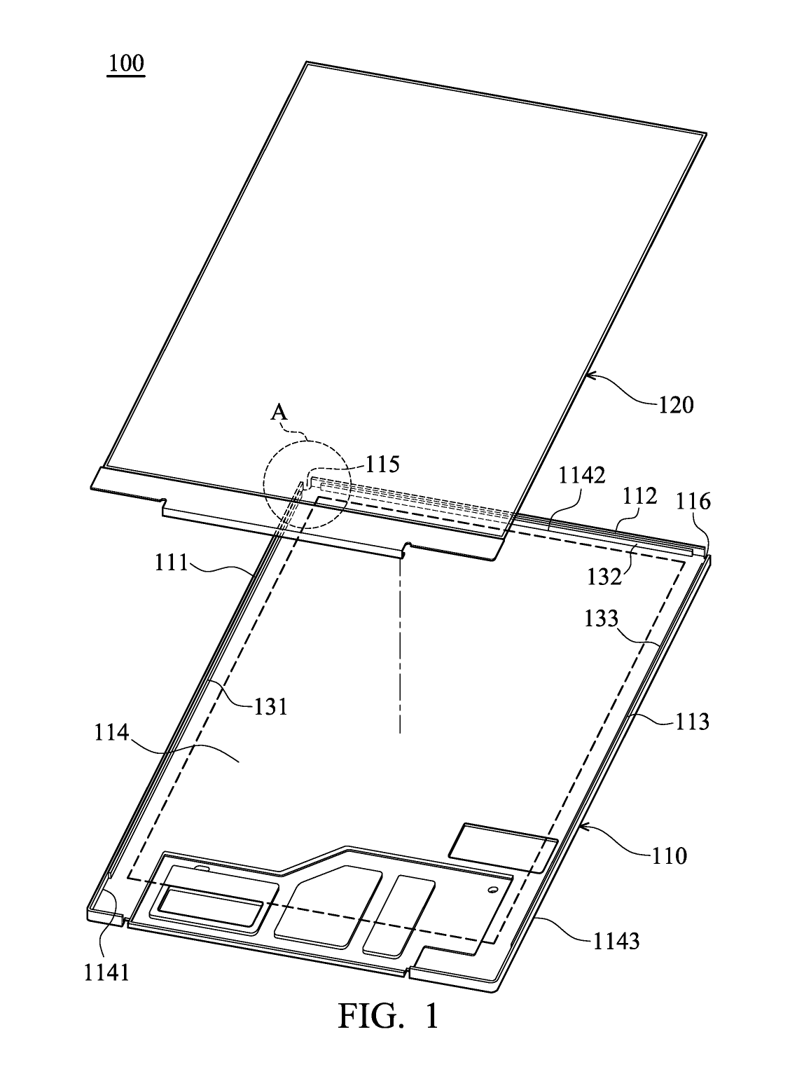

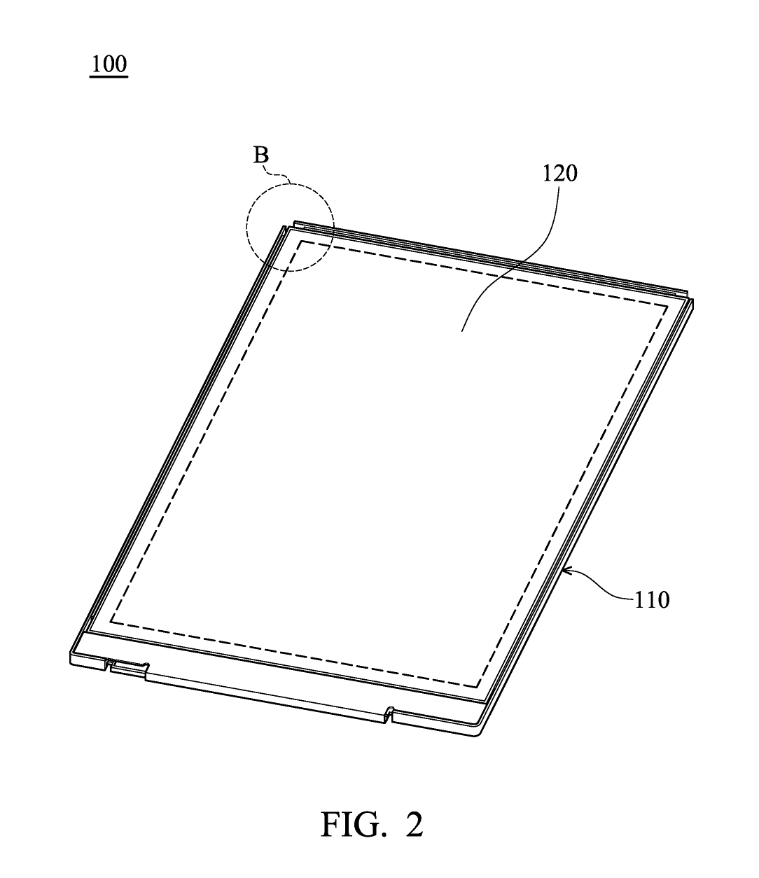

FIG. 1 shows a display module 100 of a portable electronic device of an embodiment of the invention. The display module 100 includes a frame 110, a display 120 and spacing elements 131, 132 and 133. The display 120 includes a panel (120), wherein the panel is disposed in the frame 110. The spacing elements 131, 132 and 133 are adhered to the frame 110, and disposed between the frame 110 and the panel 120. The panel (120) is detachably contacting the spacing elements 131, 132 and 133. With reference to FIG. 2, FIG. 2 is an assembly view of the display module 100. In the embodiment, the spacing elements do not fix the panel to the frame.

With reference to FIG. 1, the frame 110 is rectangular. The frame 110 comprises a base 114, a first wall 111, a second wall 112 and a third wall 113. The display 120 is disposed on the base 114. The first wall 111 is extended from a first side 1141 of the base 114 and is perpendicular thereto. The second wall 112 is extended from a second side 1142 of the base 114 and is perpendicular thereto. The third wall 113 is extended from a third side 1143 of the base 114 and is perpendicular thereto. The spacing element 131 is adhered to the first wall 111, the spacing element 132 is adhered to the second wall 112, and the spacing element 133 is adhered to the third wall 113. The second wall 112 is perpendicular to the first wall 111 and the third wall 113.

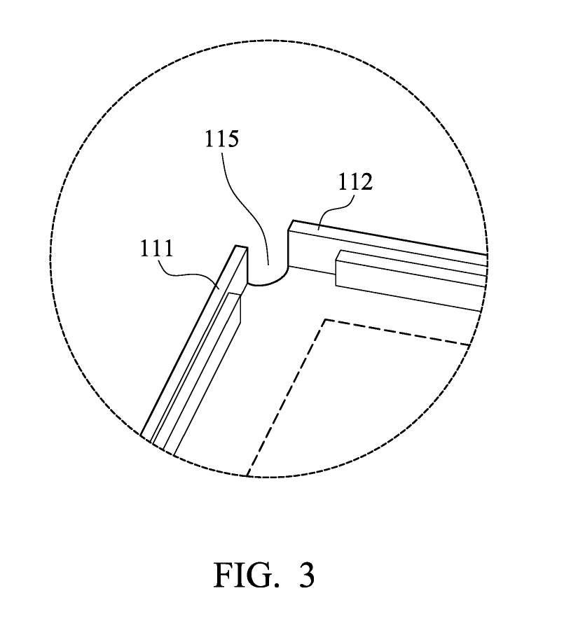

FIG. 3 is an enlarged view of portion A of FIG. 1. With reference to FIGS. 1 and 3, a first notch 115 is formed between the first wall 111 and the second wall 112. A second notch 116 is formed between the third wall 113 and the second wall 112.

In the embodiment, the spacing elements 131, 132 and 133 are respectively adhered to part of the first wall 111, the second wall 112 and the third wall 113. However, the invention is not limited thereto. In a modified embodiment, the spacing elements can be adhered to the entire wall.

The spacing elements 131, 132 and 133 are made of elastic material, and an adhesive material is disposed on a side of the spacing elements. The spacing elements 131, 132 and 133 can be, for example, tape. A thickness of the spacing element can be 0.02 mm to 1 mm. The spacing elements 131, 132 and 133 prevent the panel from contacting the frame, and ensure proper panel alignment.

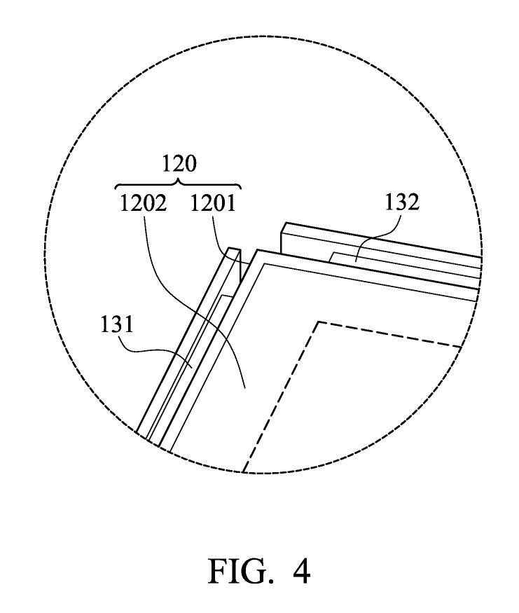

FIG. 4 is an enlarged view of portion B of FIG. 2. With reference to FIGS. 2 and 4, each of the spacing elements 131, 132 and 133 contacts a side surface 1201 of the panel 120 to align the pane 120 to the frame 110, and to prevent the panel 120 from contacting the frame 110. The side surface 1201 of the panel 120 is perpendicular to the image displaying area 1202 of the panel 120.

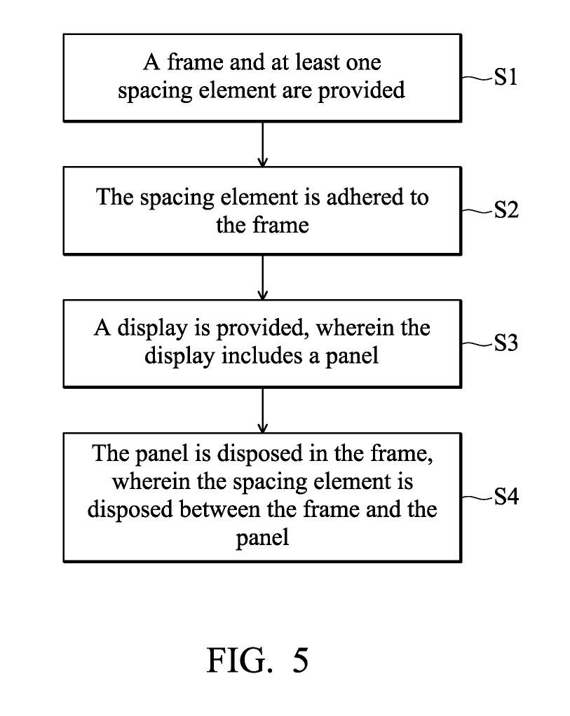

FIG. 5 shows an assembling method of the invention, which comprises the following steps: First, a frame and at least one spacing element are provided (S1). Then, the spacing element is adhered to the frame (S2). Next, a display is provided, wherein the display includes a panel (S3). Finally, the panel is disposed in the frame, wherein the spacing element is disposed between the frame and the panel (S4).

For the portable electronic device of the invention, the gap between the frame and the panel is further reduced (for example, reduced to 0.02 mm to 1 mm). Therefore, further miniaturization of portable electronic devices can be achieved. The portable electronic device can be a mobile phone, Personal Digital Assistant (PDA), automotive application device, or other electronic devices. In one embodiment, the portable electronic device can be very thin to achieve small borders.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A portable electronic device, comprising:
a frame;
a display, comprising a panel, wherein the panel is disposed in the frame; and
a first spacing element, adhered to the frame, and disposed between the frame and the panel, wherein the panel is detachably contacting the first spacing element, the frame comprises a base, a first wall, a second wall and a third wall, and the first wall is extended from a first side of the base and is perpendicular thereto, the second wall is extended from a second side of the base and is perpendicular thereto, and the third wall is extended from a third side of the base and is perpendicular thereto.

2. The portable electronic device as claimed in claim 1, wherein the portable electronic device is a mobile phone, Personal Digital Assistant or automotive application device.

3. The portable electronic device as claimed in claim 1, wherein the frame is rectangular.

4. The portable electronic device as claimed in claim 1, wherein the first spacing element is adhered to the first wall, the second wall or the third wall.

5. The portable electronic device as claimed in claim 1, further comprising a second spacing element and a third spacing element, wherein the second and third spacing elements are adhered to the second wall and the third wall respectively.

6. The portable electronic device as claimed in claim 1, wherein the second wall is perpendicular to the first and third walls, a first notch is formed between the first and second walls, and a second notch is formed between the second and third

7. A portable electronic device, comprising:
a frame;
a display, comprising a panel, wherein the panel is disposed in the frame; and
at least one spacing element, adhered to the frame, and disposed between the frame and the panel, wherein the panel is detachably contacting the spacing element, the frame comprises a base and a wall, the wall is extended from a side of the base and is perpendicular thereto, and the spacing element is applied on the wall.

8. The portable electronic device as claimed in claim 7, wherein the spacing element is applied on a part of the wall.

9. The portable electronic device as claimed in claim 7, wherein the spacing element is applied on the entire wall.

10. The portable electronic device as claimed in claim 7, wherein a thickness of the spacing element is 0.02 mm to 1 mm.

11. The portable electronic device as claimed in claim 7, wherein an adhesive material is disposed on a side of the spacing element.

12. The portable electronic device as claimed in claim 7, wherein the spacing element is made of elastic material.

13. The portable electronic device as claimed in claim 7, wherein the spacing element is tape.

14. The portable electronic device as claimed in claim 7, wherein the spacing element contacts a side surface of the panel.

15. The portable electronic device as claimed in claim 14, wherein the side surface of the panel is perpendicular to an image displaying area of the panel.

16. An portable electronic device assembling method, comprising:
providing a frame and at least one spacing element;
adhering the spacing element to the frame;
providing a display, comprising a panel; and
disposing the panel in the frame, wherein the spacing element is disposed between the frame and the panel, the frame comprises a base and a wall, the wall is extended from a side of the base and is perpendicular thereto, and the spacing element is applied on the wall.

17. The portable electronic device assembling method as claimed in claim 16, wherein the spacing element is applied on a part of the wall.

18. The portable electronic device assembling method as claimed in claim 16, wherein the spacing element is applied on the entire wall.

19. The portable electronic device assembling method as claimed in claim 16, wherein the portable electronic device is a mobile phone, Personal Digital Assistant or automotive application device.
